(19) United States
(12) Patent Application Publication
(10) Pub. No.: US 2013/0221449 A1
(43) Pub. Date: Aug. 29, 2013

(54) MANUFACTURING METHOD OF SEMICONDUCTOR DEVICE AND SEMICONDUCTOR MANUFACTURING DEVICE

(71) Applicant: Tomonori AOYAMA, Kanagawa-ken (JP)

(72) Inventor: Tomonori AOYAMA, Kanagawa-ken (JP)

(73) Assignee: KABUSHIKI KAISHA TOSHIBA, Tokyo (JP)

(21) Appl. No.: 13/607,704

(22) Filed: Sep. 8, 2012

(30) Foreign Application Priority Data
Feb. 24, 2012 (JP) 2012-038981

(51) Int. Cl. H01L 21/225; H01L 29/76

(52) U.S. Cl. CPC H01L 21/2254; H01L 29/76
USPC 257/402; 438/466; 118/723 E

(57) ABSTRACT

According to one embodiment, a manufacturing method of a semiconductor device includes forming a monolayer that includes organic compounds that contain conductive type dopants on a semiconductor layer, applying a bias voltage to the semiconductor layer, and injecting plasma inactive gas ions against the monolayer, so that conductive type dopants included in the monolayer are impacted by the ions to form the dopant layer injected with the conductive type dopants in a semiconductor layer. This manufacturing method controls the density of the conductive type dopants in the dopant layer by changing a size of functional group.

### CROSS-REFERENCE TO RELATED APPLICATION

This application is based upon and claims the benefit of priority from Japanese Patent Application No. 2012-038981, filed Feb. 24, 2012, the entire contents of which are incorporated herein by reference.

### FIELD

Embodiments described herein relate to a manufacturing method of a semiconductor device and a semiconductor manufacturing device used therein.

### BACKGROUND

A low density of dopants are implanted into a transistor (semiconductor device) channel region to control threshold voltage. However, as transistor refinement has progressed, the length of the gate has shortened leading to the narrowing of the channel domain. In the case where dopants are deposited into the channel domain of the transistor to keep the impurity density, in extreme cases, there is a possibility that no dopants for controlling the threshold voltage in the channel domain exists.

As device sizes shrink, and dopant dosages become very small, it has become difficult to control the density of the implanted dopants. For example, in the implantation techniques used heretofore, assuming that the gate length is adequate, the dopant density is averaged over the span of the channel. Accordingly, even if the resulting dopant density profile is non-uniform, there is not much effect on the transistor threshold voltage. Nevertheless, when the gate length is shortened, the transistor threshold voltage can vary greatly if the dopant density is non-uniform over the length or span of the channel.

As a method to solve this problem, a technique of implanting single ions is proposed. This is a technique in which ions are inserted one at a time into a desired position in the channel. By using this technique, implanted dopant ions can be implanted into intended positions, and thus a uniform density, within the narrow channel.

By single ion implanting, in which dopant ions is inserted one at a time, throughput suffers, and the manufacturing costs of transistors increases drastically. Therefore, using single ion insertion for mass production is difficult.

### DESCRIPTION OF THE DRAWINGS

FIGS. 1A and 1B are cross-section diagrams showing a manufacturing method of a semiconductor device of first and second embodiments.

FIGS. 2A and 2B are cross-section diagrams showing the manufacturing method of the semiconductor device of first and second embodiments.

FIGS. 3A and 3B are cross-section diagrams showing the manufacturing method of the semiconductor device of first and second embodiments.

FIGS. 4A and 4B are cross-section diagrams showing the manufacturing method of the semiconductor device of first and second embodiments.

FIG. 5 is a cross-section diagram showing the manufacturing method of the semiconductor device of first and second embodiments.

FIGS. 6A and 6B are diagrams explaining the organic compounds used in the manufacturing method of the semiconductor device of first and second embodiments.

FIGS. 7A to 7C are diagrams explaining first and second embodiments.

FIGS. 8A and 8B are diagrams explaining first and second embodiments.

FIG. 9 is a diagram explaining a manufacturing device used in the second embodiment.

### DETAILED DESCRIPTION

To provide a uniform dopant density across a channel region, a thin, self-aligning dopant containing material is deposited over the channel region, such that the dopants are regularly and predictably-spaced across the surface of the channel region. These dopant ions may then be implanted into the channel to provide a doped channel with a defined ion density.

In an embodiment, an organic compound such as pyridine triphenylborane and or ethyldene triphenylborane is used to form a regular repeating boron doped carbon ring structure across the surface of the channel region. Dopants other than boron and phosphorous may be used in conjunction with these regularly repeating and predictably-spaced structures formed over the channel region. The dopants include p and n dopants useful for doping of semiconductor materials, but may include other atoms as well.

The position and spacing of the dopant may be modified by changing the chemistry of the dopant layer. For example, when a chemistry which deposits a larger repeating structure relative to each dopant atom is deposited over the channel region, the spacing between the dopant atoms will increase. However, the deposited dopant will still have a uniform spacing and a uniform density across the channel region because of the regular repeating structure of the deposited layer. Likewise, using a chemistry which deposits a smaller repeating structure relative to each deposited dopant atom will yield a higher density of dopant atoms, but will still result in a regular and uniform spacing of the dopant atoms overlaying the channel layer.

After formation of the repeating structure over the channel region, the dopant atoms are implanted into the channel depth by bombardment of the deposited dopant layer with neutral ions. The ions may be provided by forming a plasma overlying the substrate and providing a negative bias on the substrate. The bias level influences the energy at which the neutral ions impact the dopant layer and thus the energy they impart on the dopant layer. Thus, the bias level and the mass of the ion influence the depth at which the dopants are implanted into the channel region (e.g., the channel depth).

Additionally, the constituents of the dopant layer other than the dopants may also be implanted along with the dopant. During the annealing process which follows implantation, the constituents of the dopant layer other than the dopants can help prevent diffusion of the implanted dopants from their intended position, thereby further fixing a uniform spacing (density) of the dopant atoms along the channel region.

Using traditional lithographic techniques, the P and N doped regions may be selectively formed in an underlying substrate. As will be described in more detail herein, the regions to be N doped are masked during the deposition of the material for P doping and the regions to be P doped are masked during the deposition of the material for N doping.

Implantation of the dopants may occur after each material is deposited or after both materials have been deposited over respective channel regions.

In the embodiments, a self-limiting monolayer of the material containing the dopant is deposited over the channel region. If a greater density of dopants is required in the channel region, the chemistry may be changed to increase the dopant density in the monolayer or additional monolayers may be deposited either before or after an implantation step.

In an embodiment, the method of manufacturing a semiconductor device includes forming a monolayer that includes organic compounds that contain conductive type dopants on a semiconductor layer, applying a bias voltage to the semiconductor layer, and bombarding the monolayer with ions from a plasma against the monolayer, so that conductive type dopants included in the monolayer are bombarded by the plasma ions with sufficient energy to push them into the channel region to form the dopant layer in the semiconductor layer. As described above, this manufacturing method controls the density of the conductive type dopants by changing a size of the functional group combined with the conductive type dopants to surround the conductive type dopants in these organic compounds.

The following description refers to the appended figures for explanation. The disclosure is not just limited to this embodiment. In addition, common symbols are placed for the common parts on the diagram and duplicate explanations are omitted. Furthermore, the figures are schematic views to explain the embodiments and promote understanding. While there are places where the figures, dimensions, and ratios differ from actual device, design changes can be adequately made taking into consideration the relevant explanation below and known technology.

### Embodiment 1

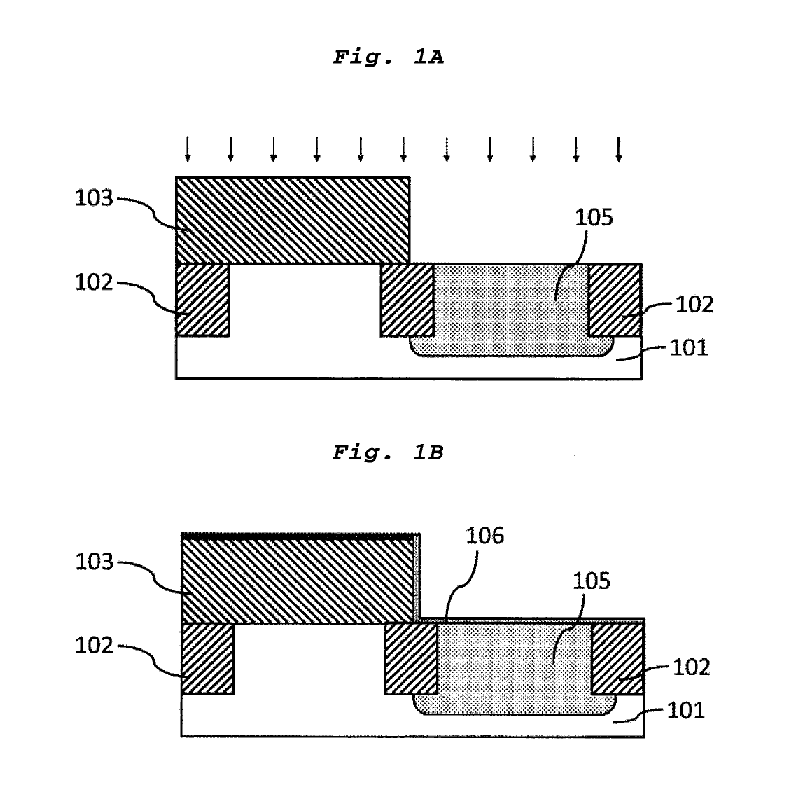

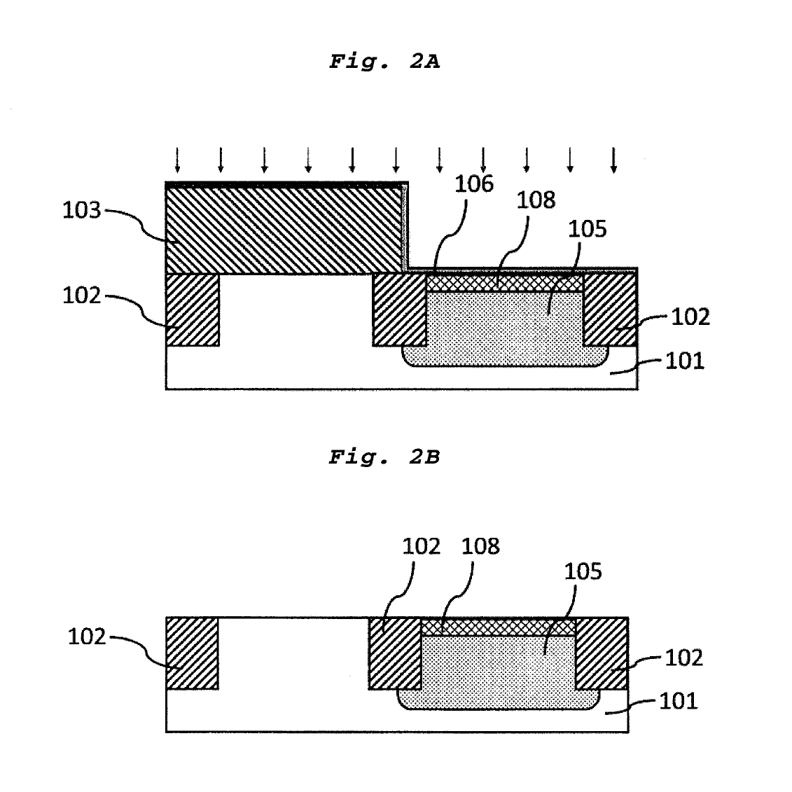

FIGS. 1A through 5, explain the manufacturing method of an implanted semiconductor structure according to an embodiment. FIGS. 1A through 5 are cross-section diagrams that show the semiconductor structure in relation to the manufacturing process of an embodiment. The conductive type dopant injection into the channel domain of the CMOS (Complementary Metal Oxide Semiconductor) transistor is explained herein as an example. Embodiments are not limited to this kind of semiconductor structure and manufacturing method.

First, referring to FIG. 1A, part of the upper surface of a silicon substrate (semiconductor layer) 101 including an element isolation region 102 is shown. A portion of the semiconductor layer 101 and separation domain 102 is covered by a resist film 103, which has been patterned to expose a region of the underlying substrate which will be implanted. Thereafter, a well 105 having B as a dopant is implanted using traditional beamline techniques. Next, referring to FIG. 1B, an organic compound layer 106, for example, pyridine-triphenylborane, is formed on top of the entire area of the silicon substrate 101 while a portion of the substrate 101 is covered with the resist film 103. This organic a compound layer 106 is a self-aligned monolayer 106 on the upper surface of the silicon substrate 101. The organic compound layer 106 is not, however, limited to a monolayer. The compound layer 106 can an organic compound layer with, for example, two or three overlapping pyridine-triphenylborane molecules. The organic compound layer 106 is explained as a monolayer 106 in below.

This pyridine-triphenylborane monolayer 106 can be formed according to the following for example. First, pyridine-triphenylborane is dissolved in an organic solvent. Next, argon and helium carrier gases are mixed in the dissolved organic solvent to make a pyridine-triphenylborane gas using a vaporizer. Then, the monolayer 106 is formed by exposing the vapor of the gaseous pyridine-triphenylborane to the upper surface of the silicon substrate 101.

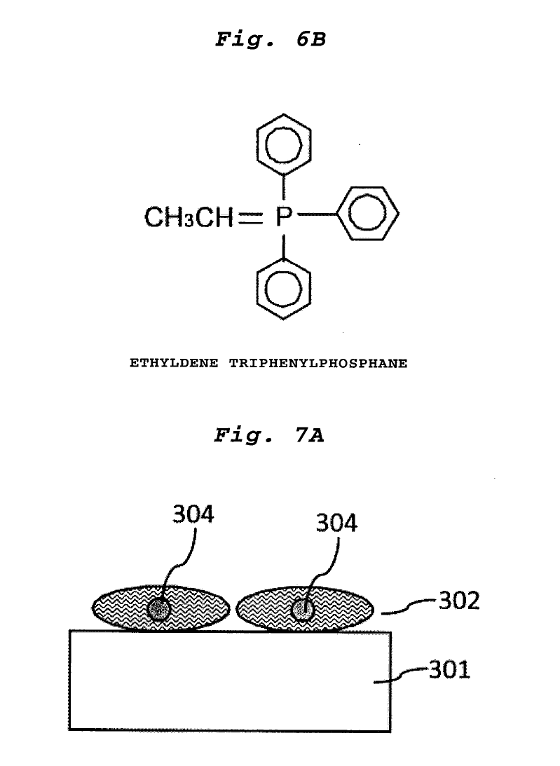

Pyridine-triphenylborane is an organic compound including boron atoms, a conductive type dopant to be injected into the silicon substrate 101, possessing a molecular composition as illustrated in FIG. 6A. According to an embodiment, the organic compound that forms the monolayer 106 is not limited to pyridine-triphenylborane. For example, the organic compound may include a P-type conductive type dopant of B, Ga (gallium), or indium atoms.

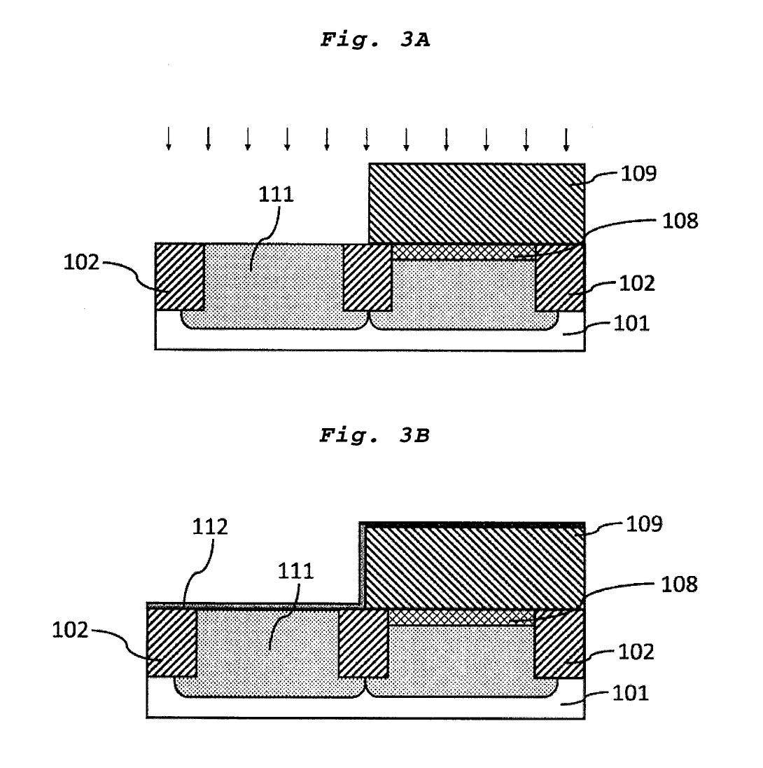

Next, referring to FIG. 2A, inert gas ions such as hydrogen (H), helium (He), neon (Ne), and argon (Ar) are injected according to the beam line method. By incidence of the inactive gas ions into the monolayer 106, the B atoms existing in the monolayer 106 of pyridine-triphenylborane are impacted by the inactive gas ions and implanted into the layer of the P-type well diffusion layer 105 domain. A P-type channel (dopant layer) 108 is thus formed. The depth of the implantation of the conductive dopant (B atoms) into the channel diffusion layer 108 of this P-type well diffusion layer 105 is controlled by the plasma ion energy bombarding the monolayer and the time during which this bombardment occurs, the ion energy being a function of the bias on the substrate.

Furthermore, carbon (C), hydrogen (H), and nitrogen (N) atoms in the pyridine-triphenylborane monolayer 106 are also implanted along with the boron atoms by the plasma ions and thereby injected into the P-type channel diffusion layer 108. During the post implant annealing process, these carbon and nitrogen atoms can work as a scatter preventing impurity to reduce the overall movement of the boron atoms implanted into the P-type channel diffusion layer 108. In addition, fluorine (F) atoms can also be injected into the P-type channel diffusion layer 108 when an organic compound containing boron B and F atoms is used as a material of the monolayer 106. These F atoms, like C and N atoms, can work to reduce scattering of B atoms injected into the P-type channel diffusion layer 108. Moreover, regarding the H atoms, for organic compounds such as pyridine-triphenylborane, even if they are injected into the channel diffusion layer 108, there are insufficient H atoms present to detrimentally affect the features of the CMOS transistor being formed. According to aspects of the present disclosure, organic compounds containing H atoms in an amount that do not cause deterioration of the underlying device being formed may be selected.

After this, the structure displayed in FIG. 2B can be obtained based on the removal of the resist film 103.

Next, referring to FIG. 3A, the P-type well diffusion layer 105 and P-type channel diffusion layer 108 formed from element separation domains 102 are covered with a resist film 109. Ion implantation of arsenic and phosphorus via beam line implanting is conducted. An N-type well diffusion layer 111 will be formed in the silicon substrate 101 by doing this.

Then, as illustrated in FIG. 3B, an organic compound layer 112, which may include ethylidene triphenylphosphane is formed on the entire upper surface of the silicon substrate 101 while the substrate 101 is covered with the resist film 109. According to aspects, the organic compound layer 112 is a monolayer aligned with the upper surface of silicon substrate 101. Aspects of the present disclosure are not limited to a monolayer. For example, the organic compound layer can be an organic compound layer with overlapping ethylidene triphenylphosphane molecules. The organic compound layer 112 is explained as a monolayer 112 in the explanation below.

The ethylidene triphenylphosphane monolayer 112, can be formed by dissolving ethylidene triphenylphosphane in an organic solvent, and with a vaporizer, forming an ethylidene triphenylphosphane vapor. The ethylidene triphenylphosphane vapor can then be exposed to the upper surface of the silicon substrate 101.

Ethylidene triphenylphosphane is an organic compound that includes P (phosphorus) atoms as conductive type dopant to be implanted into the silicon substrate 101 and possesses a molecular structure as displayed in FIG. 6B. The organic compound that forms the monolayer 112 is not limited to ethylidene triphenylphosphane. Organic compounds that contains N-type conductive type dopants P, As (Arsenic) and Sb (antimony) atoms can be used as the monolayer.

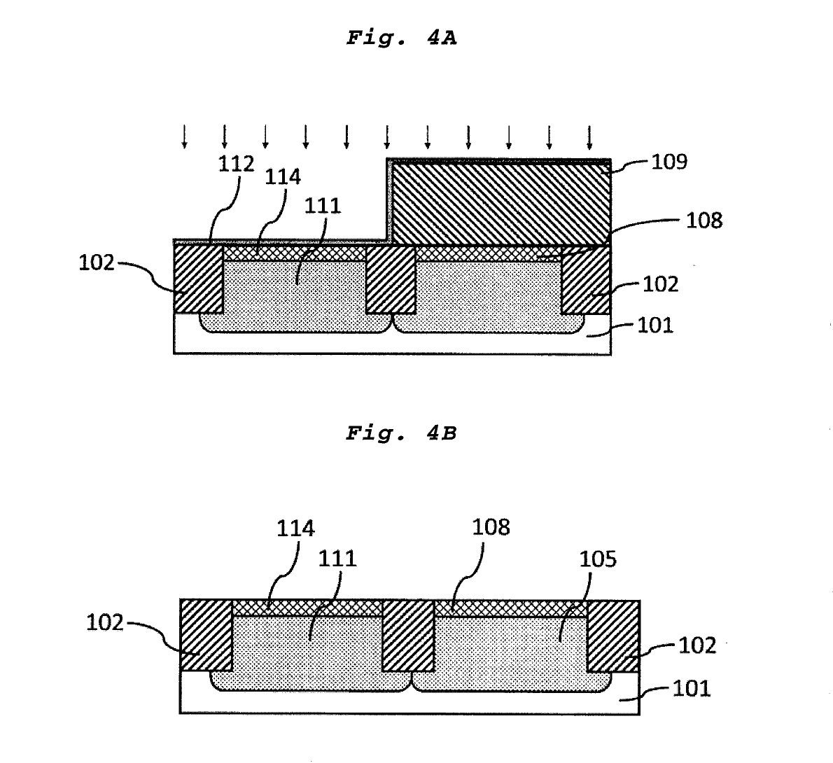

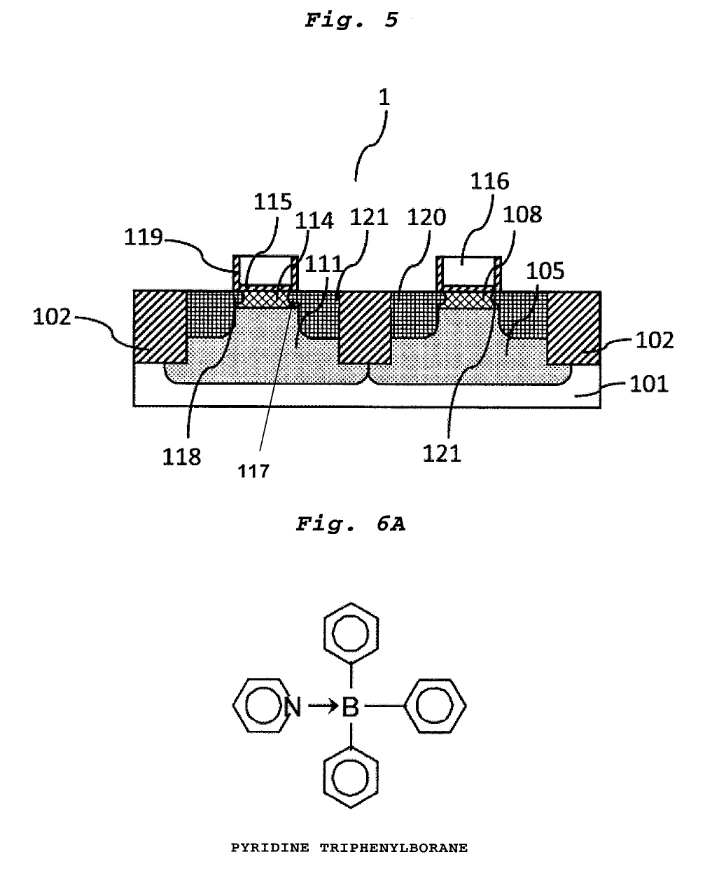

Next, a plasma of inactive gas ions such as H, He, Ne, and Ar (argon) bombard the substrate, and the monolayer, as shown in FIG. 4A. The P atoms existing in the monolayer 112 of ethylidene triphenylphosphane will be impacted by the inactive gas ions and implanted into the upper region of the N-type well domain 111. A N-type channel diffusion layer (dopant layer) 114 is formed in this way. Moreover, the injection depth of the conductive type dopant (P atom) in the channel diffusion layer 114 of this N-type diffusion well can be controlled by the impact energy of the ions and time period during which they impact the substrate.

The C and H atoms of the monolayer 112 of ethylidene triphenylphosphane are also impacted along with P atoms and are injected into the N-type channel diffusion layer 114. These C atoms reduce the movement of the P atoms implanted into the N-type channel diffusion layer 114 during the later annealing step. Again, it is not a problem to use organic compounds that include P atoms with F atoms as materials of the monolayer 112 as a modified example of the embodiment. Moreover, in regards to H atoms, for organic compounds such as ethylidene triphenylphosphane, even if they are implanted into the N-type channel diffusion layer 114, there should not be enough H atoms that would affect the performance of the CMOS transistor. According to an embodiment, an organic compound can be selected containing H atoms in an amount that does not cause deterioration to avoid weakening the attributes of the CMOS transistor.

Afterwards, the resist film 109 can be removed and the structure shown on FIG. 4B can be obtained through annealing to activate the dopants.

Following this, established methods can be used to form agate insulator 115, agate electrode 116, an N-type extension diffusion layer 117, a P-type extension diffusion layer 118, a sidewall insulator 119, an N-type source drain diffusion layer 120 and a P-type source drain diffusion layer 121, and the CMOS transistor (semiconductor device) 1, can be obtained as displayed in FIG. 5.

In addition, it is preferable to maintain a substrate temperature that does not damage the monolayers 106 and 112 that include the organic compounds prior to the implanting of the dopant from the monolayer. For example, according to an embodiment, a substrate temperate of approximately −30° C. to 100° C. may be desirable.

In an embodiment, the conductive type dopants included in the monolayer of organic compounds are impacted by inactive gas ions. The conductive type dopants are implanted into the silicon substrates in a regular repeating pattern which substantially replicates the repeating pattern of the dopants in the self aligned monolayer. Accordingly, it is possible to precisely implant conductive type dopants to the desired density or spacing, without the need to individually implant individual atoms singularly. Therefore, since it is possible for dopants to be implanted into the silicon substrates uniformly and precisely at a desired infusion depth even with low density conductive type dopants (i.e. 1E12 atoms/cm2), the non-uniformity of dopant density can be reduced. For example, even if the gate length is less than 20 nms in a CMOS transistor, since it is possible to inject conductive type dopants into the channel domain uniformly and precisely, the resulting variance of the threshold voltage from transistor to transistor is small. Accordingly, a good CMOS transistor can be formed.

Below, FIGS. 6A through 8B are used to explain the mechanisms that make implantation possible at almost uniform intervals on the silicon substrates for B, P, and As as conductive type dopants included in the monolayer.

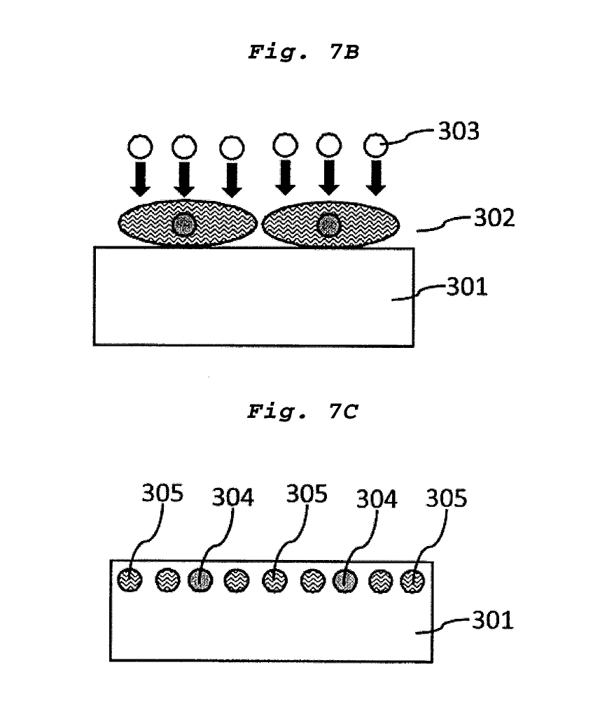

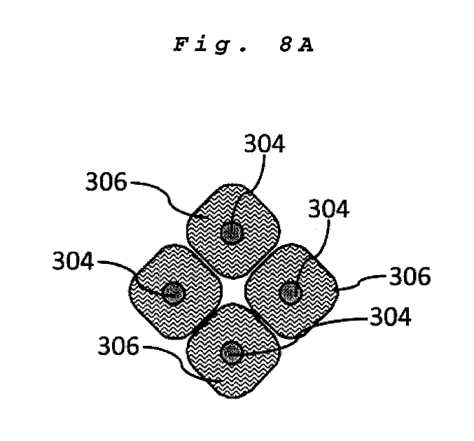

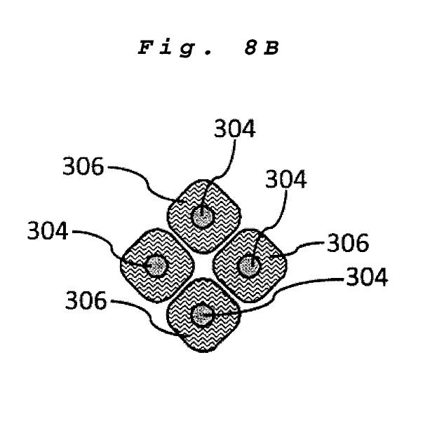

First, an organic compound monolayer 302 can be formed that contains B, P, and As conductive type dopants 304 on a silicon substrate 301 as shown in FIG. 7A. Pyridine-triphenylborane shown in FIG. 6A and ethylidene triphenylphosphane shown in FIG. 6B are used as the organic compounds in the embodiment. For example, in the case that pyridine-triphenylborane is used, the B atom 304, phenyl group, and pyridine align to form a monolayer 302. The monolayer is formed by lining up pyridine-triphenylborane such that the B atoms 304 are regularly and uniformly spaced from one another, which is a self aligning feature of the molecule when deposited as an atomic layer.

Next, inactive gas ions 303 are directed, at a desired energy set by the bias on the substrate or underlying support, at the top surface of the silicon substrate 301 as shown in FIG. 7B. The conductive type dopant 304 included in monolayer 302 is impacted upon by the directed inactive gas ions 303 and thereby implanted into the silicon substrate 301. Moreover, as illustrated in FIG. 7C, N and C atoms 305 are implanted along with the conductive type dopant 304. As explained previously, since the intervals of conductive type dopants 304 are nearly regular and repeating in the monolayer 302, the individual atoms of the conductive type dopant 304 will be implanted at almost equal intervals in the silicon substrate 301 as is shown in FIG. 7C.

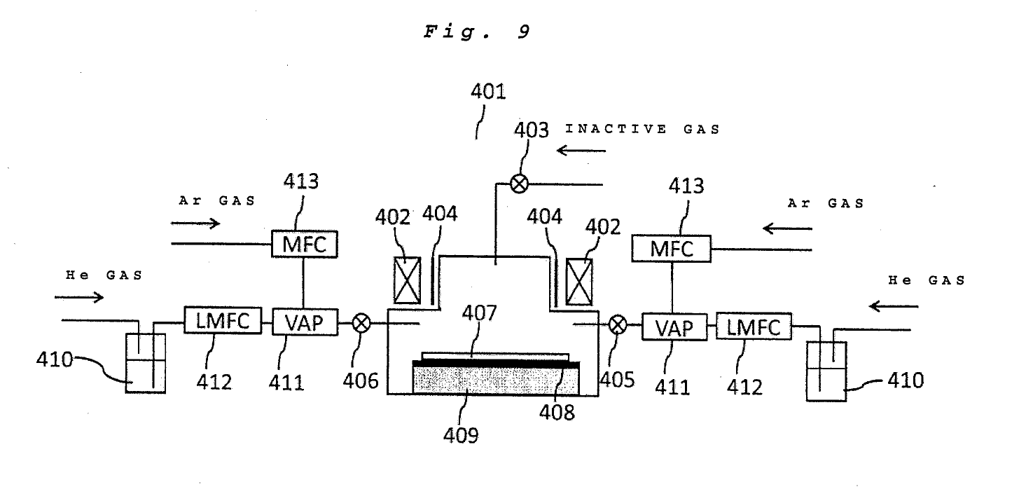

In this way, the intervals of the conductive type dopant 304 implanted into the silicon substrate 301 can be controlled by the conductive type dopant 304 interval in the monolayer 302. Referring to FIGS. 8A and 8B, the interval of conductive type dopants 304 in the monolayer 302 can be controlled based on the variation of functional group 306 size which surrounds the conductive type dopant 304 in the monolayer 302. For example, in the case that it is necessary to narrow the interval between B atoms in the monolayer 302, the size of the functional group may be reduced as is shown by comparing functional group 306 in FIG. 8A with functional group 306 in FIG. 8B. That will be realized by, for example, making pyridine borane by substituting the phenyl group of pyridine-triphenylborane with hydrogen, thereby reducing the size of the functional groups positioned between the B atoms (refer to FIG. 6A). Alternatively, to broaden the intervals between B atoms in the monolayer 302, the size of the functional group may be increased as is shown by comparing functional group 306 in FIG. 8A with functional group 306 as in FIG. 8B. For example, that can be realized by adding methyl and butyl groups to the phenyl group of pyridine-triphenylborane and by replacing the phenyl with naphthyl to make pyridine-triphenylborane so as to successfully enlarge the size of the functional groups positioned between the B atoms (refer to FIG. 6A). By controlling the intervals between the conductive type dopant 304 in the organic compound monolayer 302 in this way, the interval between the conductive type dopant 304 infused into the silicon substrate 301 can be controlled. This in turn can control the density of the conductive type dopant 304 to be injected. Furthermore, while pyridine-triphenylborane and ethyldene triphenylphosphane are used as materials of the monolayer 302 in the embodiment, aspects of the present disclosure are not so limited. Organic compounds including B, P, and As conductive type dopants 304 can be synthesized relatively easily so that the intervals of the conductive type dopants 304 are placed in an effort to correspond to the desired infused density of the conductive type dopant 304.

Moreover, since the B, P, and As conductive type dopants are implanted at a low density in the embodiment, a monolayer without overlapping organic compound molecules are used. To raise the density of the conductive type dopants, overlapping layers of, for example, two or three organic compound molecules may be used. Even in this case, the density of the conductive type dopants can be precisely controlled. These additional layers may be formed so that multiple monolayers are present at the plasma ion bombardment step, or individual monolayers, with plasma ion bombardment occurring between monolayer formation steps, may also be employed.

### Embodiment 2

This embodiment differs from Embodiment 1, by implanting conductive type dopants into a silicon substrate by applying high frequency bias using H, He, Ne, and Ar inactive gas ions formed from plasma (e.g., plasma doping). In this way, it is possible to infuse the conductive type dopants in a short time as compared to Embodiment 1. In addition, the direction of ion infusion used in Embodiment 1 is defined so that places exist where injection is not possible. In this embodiment, since infusion direction will not be limited because of the plasma doping method being used, the conductive type dopants can be injected into the silicon substrate surfaces like side surface silicon channels on 3D structural devices such as FinFET, surround gate transistor, and BiCS (Bit-Cost-Scalable). Moreover, transistors such as FinFET can be used as memory device driver transistors. MRAM (Magneto resistive Random Access Memory), for example, is cited as a memory device triggered by the transistors.

The figures that explain the manufacturing method of Embodiment 2 of semiconductor device is shown similarly as the figures used to explain Embodiment 1 and as such the manufacturing method of semiconductor device for Embodiment 2 is explained in FIGS. 1A through 5. A detailed explanation regarding the common parts with Embodiment 1 will be omitted here. Below is an explanation of the implanting of dopants into the channel domain of CMOS transistors as an example, but as in Embodiment 1, this disclosure is not limited to this kind of semiconductor device and manufacturing method.

First, part of the upper surface of the silicon substrate 101 in which element separation domain 102 is formed is covered by a resist film 103 as is shown in FIG. 1A as in Embodiment 1. B and other ions may be ion-implanted according to the beam line method to form the P-type well diffusion layer 105 in the silicon substrate 101.

While the substrate is covered by the resist film 103 as illustrated in FIG. 1B, a monolayer 106 that includes pyridine-triphenylborane is formed on the entire upper surface of the silicon substrate 101. The organic compound that forms the monolayer 106 is not limited to pyridine-triphenylborane, so long as it includes P-type conductive type dopants such as B, Ga, and In. In the case that these conductive type dopants are implanted into the silicon substrate 101 at desired intervals, it is preferable to choose organic compounds which form a repeating pattern at desired intervals. In addition, it is beneficial to use an organic compound layer with, for example, two or three overlapping pyridine-triphenylborane molecules instead of the monolayer 106 as in Embodiment 1.

Next, inactive gas ions such as H, He, Ne, and Ar which are formed in plasma are projected toward the silicon substrate 101. The inactive gas ions are applied with a high frequency bias voltage by application of high voltage to electrodes within chamber as is displayed in FIG. 2A. Since the inactive gas ions are projected into the monolayer 106, the B atoms existing in the pyridine-triphenylborane monolayer 106 are impacted on by such gas ions with sufficient energy to implant the B atoms into the upper region of the P-type well diffusion layer 105. Accordingly, the P-type channel diffusion layer 108 is formed. After this, the resist film 103 is removed, resulting in the structure displayed in FIG. 2B. Moreover, the infusion depth of the conductive type dopant (B atom) against this P-type channel diffusion layer 108 can be controlled by the magnitude of the bias voltage on the silicon substrate 101 (or substrate support) and incidence time. In addition, the frequency of bias voltage applied to the silicon substrate 101 is selected depending on the plasma inactive gas ion charge, that is, such that an amount of the inactive gas ion drawn to the silicon substrate 101 is to be optimal. The radio wavelength of 13.56 MHz can be used, for example.

Next, the P-type well diffusion layer 105 and P-type channel diffusion layer 108 are covered by a resist 109 to form the other part of upper surface of the silicon substrate 101, as illustrated FIG. 3A. As and P ions are ion-implanted according to the beam line method. The N-type well diffusion 111 in the silicon substrate 101 is formed in this way. Then, the monolayer 112 including ethylidene triphenylphosphane is formed on the entire upper surface of the silicon substrate 101, including the resist film 109 as shown in FIG. 3B. As in Embodiment 1, the organic compounds that form the monolayer 112 are not limited to those including the N-type conductive type dopants such as P, As and, Sb but in the case that this conductive type dopant is injected into the silicon substrate 101 at desired intervals, it is best to select the organic compounds appropriate with these desired intervals. In addition, it is good to use the organic compound layer that overlaps two or three ethylidene triphenylphosphane molecules instead of the monolayer 112 as in Embodiment 1.

Next, FIG. 4A, the inactive gas ions, such as H, He, Ne and, Ar that are in a plasma state due to the application of high voltage into the gas in the chamber, are projected toward the silicon substrate 101 that is biased with high frequency power. The P atoms existing in the ethylidene triphenylphosphane monolayer 112 are impacted by projected inactive gas ions and are implanted into the top layer of the N-type well 111 region. The N-type channel diffusion layer 114 is formed in this way. The structure shown in FIG. 4B can be obtained by removal of the resist film 109. Furthermore, the infusion depth of the conductive type dopant (P atom) in this N-type channel diffusion layer 114 can be controlled by the magnitude of the silicon substrate 101 bias voltage and total exposure time to bombardment by the plasma ions. Moreover, it is better to select the bias voltage frequency to apply to the silicon substrate 101 in response to the charge of the plasma inactive gas ion.

Next, FIG. 9 will be used to explain a manufacturing device used in the embodiment.

A chamber 401, as shown in FIG. 9, possesses a susceptor (stage) 409 which houses an electrode 408 for substrate bias, and a silicon substrate 407 is placed on top of the susceptor 409. It is possible to draw the inactive gas ions to the silicon substrate 407 based on the electrode 408 for this substrate bias (voltage application part). Accordingly, the conductive type dopants included in the organic compound monolayer that is formed on the surface of the silicon substrate 407 can be impacted. Furthermore, it is desirable to have functions that can regulate a temperature for the susceptor 409.

In addition, the chamber 401 possesses two material tanks 410 and this material tank connects chamber 401 through a liquid mass flow controller 412, a vaporizer 411, valves (provision part) 405 and 406. In the two material tanks 410, there are organic compound solutions containing the P-type conductive type dopants (e.g., B) and those containing N-type conductive type dopants (e.g., As and P) and their solutions are mixed with argon gas (carrier gas) and the like, regulated and sent via a mass flow controller 413 into the vaporizer 411 and gasified. Furthermore, the gasified organic compounds are distributed into the inside of the chamber 401. The chamber 401 is not limited to two material tanks 410. It may include one, two or more.

Moreover, the chamber 401 includes the valve 403 (supply part) to supply the inactive gases such as H, He, Ne and Ar. In addition, the chamber 401 has a pair of electrodes 404 that make the inactive gases into plasma and a coil 402. The coil 402 regulates the magnetic field inside the chamber 401 and keeps the plasma generated by the electrode 404 from touching the inner wall of chamber 401. By doing this, the coil 402 prevents plasma from undermining the inner wall of chamber 401 and polluting the CMOS transistor. RF (Radio Frequency), ICP (Inductively-Coupled Plasma) and ECR (Electron Cyclotron resonance) outlets can be used for plasma outbreak power supplies and RF outlets can be used for bias voltage power supplies.

According to the embodiment, it is possible that by forming organic compound monolayers containing the conductive type dopants on a silicon substrate and then by incidence of the inactive gas ions formed by plasma into the silicon substrate applied with the high frequency bias, the conductive type dopants including the inactive gas ions that are projected into the organic compounds are impacted and those conductive type dopants can be injected into the silicon substrates at virtually equal intervals. Therefore, since it is possible to inject low density conductive type dopants at a desired depth into the silicon substrates precisely, it is possible to reduce the non-uniformity of dopant density across a channel region. As such, even in a narrow CMOS transistor, conductive type dopants can precisely be injected into that channel the domain, the dispersion of threshold voltage is small, and a good CMOS transistor can be formed. In addition, according to the embodiment, by using this plasma doping method, since multiple inactive gas ions can be injected into the domain possessing fixed area, a shorter time can be used to inject the conductive type dopants compared to Embodiment 1. Moreover, with the ion-implanting used in Embodiment 1 the direction of ion projection is determined so in the case that ion is projected into the monolayer of the silicon substrate possessing a complex surface, there may be places where projection is not possible. Nonetheless, in the plasma doping method directions for projecting ions are not limited and therefore ions can be implanted into the silicon substrate monolayer that possesses complex surface. In the case where there is a trench in the surface of the silicon substrate and the organic compound monolayer is formed covering the inner side wall of that trench, for example, since ion-implanting direction is determined, projecting ions inside the trench is difficult and projecting ions into the entire monolayer covering the side wall cannot be achieved. However, in the plasma doping method, plasma (ions) enter the inside of the trench and can project ions into the entire monolayer covering the trench side wall because they are drawn in by bias voltage applied to the silicon substrate. Therefore, even if the silicon substrate surface is a complex structure, ions can be projected into the silicon substrate monolayer and as a result conductive type dopants can be injected uniformly into the silicon substrate.

In addition, the manufacturing device is to be one which includes a supply part that introduces the inactive gases and a supply part that introduces the organic compounds that contain conductive type dopants, and includes a chamber that includes a power supply to make the inactive gas into plasma and a power supply to apply bias onto the substrate. Therefore, it is easy to provide a manufacturing device that can realize process flow that injects conductive type dopants.

Moreover, the silicon substrates do not necessarily have to be silicon substrates for Embodiments 1 and 2 but can be other substrates (for example, SOI, Silicon on insulator substrate, and SiG substrates, etc). As well, the semiconductor structures formed on various substrates can also be good and semiconductor layers that are devices with three-dimensional structure will also do.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device, comprising:
forming a regularly repeating layer on a semiconductor layer, wherein the regularly repeating layer contains conductive type dopants; and
bombarding the regularly repeating layer with inert gas ions so the conductive type dopants of the regularly repeating layer are impacted by the inactive gas ions.

2. The method of claim 1, wherein the regularly repeating layer is an organic compound layer having a functional group.

3. The method of claim 2, wherein atoms of the organic compound layer other than conductive type dopants are also implanted into the semiconductor layer.

4. The method of claim 2, wherein the organic compound layer is a monolayer formed on the semiconductor layer.

5. The method of claim 2, wherein the organic compound layer includes two or more monolayers formed on the semiconductor layer.

6. The method of claim 2, wherein the organic compound layer includes at least one of pyridine triphenylborane or ethyldene triphenylborane.

7. The method of claim 2, wherein the organic compound layer is formed of a regular, repeating structure of the dopants.

8. The method of claim 2, wherein forming the organic compound layer on the semiconductor layer comprises:
selectively doping P and N regions, wherein selectively doping the P and N regions comprises masking regions to be N-doped during deposition of material for P-doping and masking regions to be P-doped during deposition of material for N-doping.

9. The method of claim 8, further comprising applying a resin mask to selectively dope the P and N regions.

10. The method of claim 1, wherein elements of the functional group are implanted into the semiconductor layer.

11. The method of claim 1, wherein the depth of dopant implantation into the semiconductor layer is controlled by a bias level at which the inactive gas ions are bombarded into the organic compound.

12. The method of claim 1, further comprising applying a bias voltage on the semiconductor layer.

13. A semiconductor manufacturing device, comprising:
a first supply part that provides organic compounds containing dopants;
a second supply part that provides inactive gas;
a pair of electrodes that convert the inactive gas into plasma to form an organic compound layer containing the dopants on a semiconductor substrate; and
a stage for holding the semiconductor substrate, wherein the stage is equipped with a voltage application part to apply a bias voltage to the semiconductor substrate.

14. The manufacturing device of claim 13, further comprising coils which regulate a magnetic field inside the manufacturing device in an effort to keep the plasma from touching an inner portion of the manufacturing device.

15. The manufacturing device of claim 13, wherein the organic compound formed on the semiconductor substrate is a monolayer.

16. The manufacturing device of claim 15, wherein the plasma bombards the monolayer to implant the dopants into the semiconductor substrate at regular and predictably spaced regions in the substrate.

17. The manufacturing device of claim 13, wherein the organic compounds includes at least one of pyridine triphenylborane or ethyldene triphenylborane.

18. The manufacturing device of claim 13, wherein the first supply part comprises a first material tank for organic compounds containing P-type conductive dopants and a second material tank for organic compounds containing N-type conductive dopants.

19. The semiconductor device, comprising:
a dielectric film formed on a substrate;
an electrode formed on the dielectric film; and
a channel diffusion layer formed in the substrate on a side of the dielectric film that is opposite the electrode, the diffusion layer containing one of carbon, hydrogen and nitrogen.

20. The semiconductor device of claim 19, wherein the diffusion layer containing one of carbon, hydrogen and nitrogen is formed from one of pyridine triphenylborane and ethyldene triphenylborane.
